(19) United States
(12) Patent Application Publication
(10) Pub. No.: US 2009/0009172 A1
(43) Pub. Date: Jan. 8, 2009

(54) MAGNETIC RESONANCE APPARATUS PATIENT SUPPORT

(76) Inventors: Peter Feld, Nuernberg (DE); Hubertus Fischer, Bamberg (DE); Ludwig Kreischer, Dormitz (DE); Wilfried Schnell, Forchheim (DE)

Correspondence Address: SCHIFF HARDIN, LLP;PATENT DEPARTMENT, 6600 SEARS TOWER, CHICAGO, IL, 60606-6473, US

(21) Appl. No.: 12/166,860

(22) Filed: Jul. 2, 2008

(30) Foreign Application Priority Data
Jul. 2, 2007 (DE) 10 2007 030 629.8

(51) Int. Cl. G01R 33/30

(52) U.S. Cl. 324/321

(57) ABSTRACT

An arrangement for supporting a patient in a magnetic resonance apparatus includes a platform that accommodates the patient for a magnetic resonance examination to be conducted, local coils for the magnetic resonance examination and fastening belts, with the fastening belts being fashioned to affix the local coils on the patient and the local coils are at least partially integrated into the respective fastening belts.

### BACKGROUND OF THE INVENTION

1. Field of the Invention

The invention concerns an arrangement for supporting a patient in a magnetic resonance apparatus.

2. Description of the Prior Art

In a magnetic resonance examination, local coils required for examination of a patient are attached on his body with the aid of belts. Coils known as “bottom coils” are most often placed on the bed or platform on which the patient lies in the magnetic resonance data acquisition unit (“scanner”). The coils have a rigid housing that is fashioned to accommodate the patient weight. Coils known as “top coils” are placed on the patient and are fixed on the body of the patient and on the bed or platform with the aid of fastening straps.

Cables that are electrically connected with the magnetic resonance apparatus via a plug connection are located at the local coils. Corresponding plug receptacles for the coil plugs arranged on the cables are normally located in the bed or platform.

If necessary, the patient to be examined can also be fixed on the bed or platform with additional belts in order to be able to implement the magnetic resonance examination.

In conventional magnetic resonance apparatuses, these measures are very time-consuming and can be implemented only by implementing a number of operating steps.

The time duration required for preparation of a magnetic resonance examination is several minutes and therefore cannot be disregarded with regard to the total time duration required for the MR examination.

Since the described measures for preparation of the MR examination occur directly at the magnetic resonance apparatus, the total number of possible MR measurements (throughput) is significantly limited in terms of time by the intensive preparation time.

### SUMMARY OF THE INVENTION

An object of the present invention is to provide an arrangement for supporting a patient in a magnetic resonance apparatus that allows a simplified patient preparation with less time expenditure.

In the arrangement according to the invention for supporting a patient in a magnetic resonance apparatus, a bed or platform accommodates the patient for a magnetic resonance examination to be conducted, and at least one local coil for the magnetic resonance examination and at least one fastening belt are used, and the fastening belt is fashioned to affix the local coil on the patient, and the local coil is arranged at least partially integrated into the fastening belt.

Due to the arrangement according to the invention, the necessity of exchanging or fastening local coils to one or more fastening belts that are separate from the coils is for different examinations is avoided.

The necessity to have to repeatedly connect or disconnect respective local coils is also avoided.

Due to the simplification in the handling that is enabled by the arrangement according to the invention, more patients can be examined per time unit and the reliability and availability of the magnetic resonance apparatus and the required MR components are increased.

In a preferred embodiment, the electrical contacts or connections of the local coil are integrated into the mechanical connections or fasteners of the fastening belt.

In a preferred embodiment, the platform or bed is adapted to the patient with the fastening belt system according to the invention. Local coils integrated into the fastening belt are advantageously electrically connected with the platform at lateral edges of the platform.

As noted above, the mechanical connection of the fastening belt with the platform then also occurs at the lateral edges, preferably via the integrated mechanical-electrical connections.

In this case the employed local coils exhibit standardized lengths and are adapted to the body of the patient by overlapping. Due to the overlapping and the standardized lengths of the local coils, only a few local coils can be used to image the entire body, or anatomical sub-regions to be examined. Inexpensive manufacture of the local coils is enabled by the standardization.

In a preferred embodiment, the platform with the fastening belt system according to the invention is connected with the magnetic resonance apparatus such that it can be separated therefrom.

A fast exchange of platforms is thereby enabled. For example, a first patient undergoes a magnetic resonance examination using a first platform while a second patient is prepared for examination in a preparation room using a second platform. In emergency situations, a fast examination and transfer of the patient can ensue together with the platform associated with the emergency patient.

In a preferred embodiment, the local coil electronics required for operation of the local coil are completely integrated into the platform. The local coil electronics include circuits for adaptation of a particular local coil, for detuning the local coil, and for preamplification of signals of the local coil, for example.

The local coils integrated into the fastening belts preferably are connected galvanically or via a capacitive or inductive coupling with the electronics of the platform. The connection is preferably identically designed for multiple local coils in order to enable a cost-effective manufacture.

In a further preferred embodiment, local coils that are not needed for examination are detuned.

In a preferred embodiment, the local coils each exhibit an identical width. The local coils therefore differ only in their respective lengths. A cost-effective manufacture is therefore enabled.

In a preferred embodiment, fastening belts with integrated local coils (in particular with integrated top coils) are designed to be flexible and limp (slack) in order to enable an optimal adaptation of the local coils to the respective bodies of many patients.

The flexible, limp (soft) embodiment of the top coils is additionally facilitated by the aforementioned arrangement of the local coil electronics in the platform. Both the handling capability of the fastening and examination system and the comfort of the patient are increased.

In a preferred embodiment, the fastening belts form part of the platform so that the local coils integrated into the fastening belts do not have to be exchanged dependent on the patient.

In a preferred embodiment, the fastening belts with the integrated local coils are designed to simultaneously fix the patient on the platform.

In a preferred embodiment, the fastening belts with integrated top coils are advantageously fashioned overlapping in order to be able to adapt the fastening belts to the respective patient's body with the aid of hook-and-loop fasteners, for example.

In addition to providing strong coupling, overlapping local coils have a high noise correlation and can thus be detected and taken into account by the magnetic resonance system.

A highly customized adaptation to an individual body shape is possible by a partial lateral overlapping of the fastening belts.

Additional flexibly designed local coils integrated into a fastening belt can advantageously be replaced in the head region with self-supporting and rigidly designed local coils.

In a preferred embodiment, the fastening belts that contain integrated top coils are plugged in at the sides of the platform and can be connected above the patient by a hook-and-loop fastener, for example.

A geometric or magnetic decoupling of local coil elements is enabled by a partially overlapping arrangement of the local coils or local coil elements integrated into the fastening belts.

An electrical decoupling of the local coil elements can additionally ensue.

The decoupling of local coil elements can also be influenced by a predetermined structure in the hook-and-loop fastener. This can be designed such that the fastening belt can be loosened or tightened in steps. The possible overlap of the local coil elements of the two parts of the belt is therefore altered in discrete steps so that an optimal magnetic decoupling of coil elements is formed in the individual belt pairs.

For example, a reproducible mechanical and electrical coupling is achieved by a simple detent of the hook-and-loop fastener.

### BRIEF DESCRIPTION OF THE DRAWINGS

FIG. 1A shows a magnetic resonance patient platform in accordance with the present invention without a patient thereon.

FIG. 1B shows the platform of FIG. 1A, with a patient thereon.

FIG. 2 is a cross-section of the patient platform with fastened belts in accordance with the present invention.

### DESCRIPTION OF THE PREFERRED EMBODIMENTS

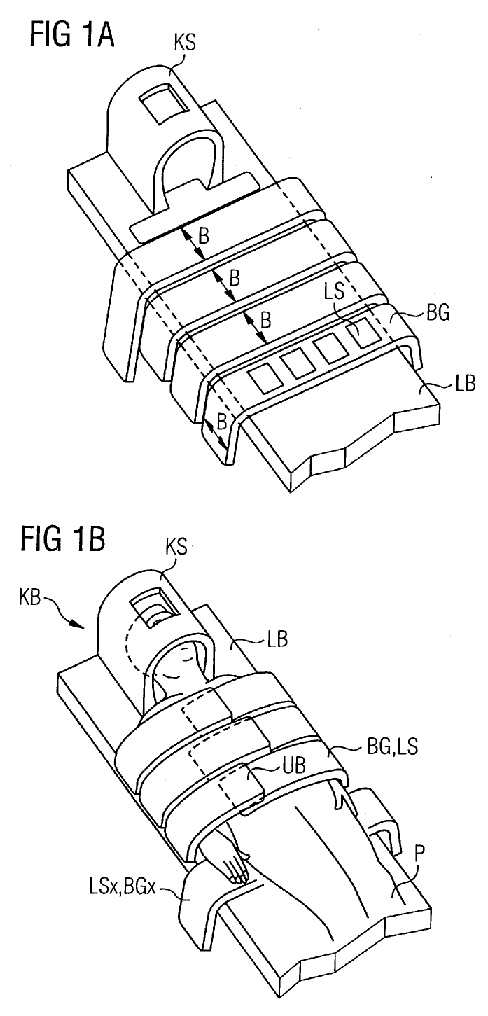

FIG. 1A shows a magnetic resonance patient platform LB without a patient and FIG. 1B shows the platform LB with a patient P thereon, in each case with local coils LS integrated into respective fastening belts BG.

The platform LB for accommodation of the patient P for a magnetic resonance examination to be conducted, the local coils LS for magnetic resonance examination, and fastening belts BG are used in the arrangement according to the invention for supporting a patient P in a magnetic resonance apparatus. The fastening belts BG are fashioned to fix the local coils LS on the patient P. The local coils LS are arranged at least partially integrated into the fastening belts BG.

The respective local coils LS preferably have identical widths B. The local coils LS therefore differ only in their respective lengths.

The fastening belts BG with the integrated local coils LS are designed to be flexible and limp in order to enable an adaptation of the respective local coils LS to the body of the patient P.

As can be seen, the fastening belts BG with the integrated local coils LS are designed to simultaneously fix the patient P on the platform LB.

The fastening belts BG overlap in a region UB that preferably has a hook-and-loop fastener in order to be able to adapt the fastening belts BG to the patient P.

Instead of the flexibly designed fastening belts BG, a self-supporting and rigidly designed local coil KS can be used in a head region KB.

Local coils LSx and their associated fastening belts BGx that are not used for examination are closed in order to avoid damage to them upon insertion of the patient into the magnet opening. In the event that they do not contribute to the imaging, they can possibly be detuned in order to further improve the image quality. This detuning ensues through local coil electronics integrated into the platform LB, for example.

Before the insertion of the patient P into the magnetic resonance apparatus, a monitoring circuit can ensure that all flexible fastening belts or local coils are closed over the patient.

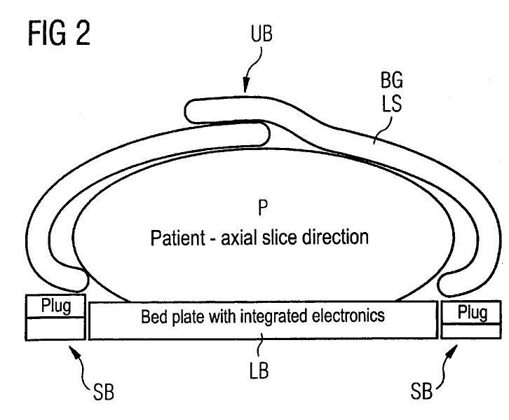

FIG. 2 shows a cross-section of the platform LB with the fastening belts BG designed according to the invention in an advantageous embodiment.

It is advantageous when the fastening belts BG with the integrated coils are plugged laterally into the platform LB as “coil belts” and are electrically connected with the platform LB such that the fastening belts BG are optimally adapted to conform close to the body of the patient P over a maximum length.

For this purpose, a plug region SB can be provided at the platform LB. This enables different positions for the electrical connection between the integrated coils of the fastening belt BG and the platform LB through correspondingly designed plug connections.

An optimal adaptation of the “coil belts” to the body shape of different patients thus can be achieved.

Although modifications and changes may be suggested by those skilled in the art, it is the intention of the inventors to embody within the patent warranted hereon all changes and modifications as reasonably and properly come within the scope of their contribution to the art.

We claim as our invention:

1. An arrangement for supporting a patient in a magnetic resonance apparatus, comprising:
a platform configured to receive a patient thereon and configured for insertion into a magnetic resonance data acquisition apparatus to implement a magnetic resonance examination of the patient on the platform;
at least one local coil configured for emitting or receiving radio-frequency signals in the implementation of said magnetic resonance examination;
at least one fastening belt that affixes the local coil on the patient to implement magnetic resonance examination; and
said local coil being at least partially integrated into the fastening belt.

2. An arrangement as claimed in claim 1 comprising local coil electronics, that operates said local coil in the implementation of said magnetic resonance examination, completely integrated into said platform, and in electrical communication with the local coil.

3. An arrangement as claimed in claim 2 wherein said local coil electronics comprises at least one circuit selected from the group consisting of a circuit that electromagnetically adapts the local coil to implement said magnetic resonance examination, a circuit that detunes the local coil, and a circuit that pre-amplifies signals detected by the local coil.

4. An arrangement as claimed in claim 2 comprising a coupling arrangement that operationally couples said local coil and said local coil electronics, said coupling arrangement being selected from the group consisting of galvanic coupling arrangements, capacitive coupling arrangements, and inductive coupling arrangements.

5. An arrangement as claimed in claim 4 comprising a plurality of local coils and a plurality of local coil electronics respectively coupled to the plurality of local coils, via a plurality of coupling arrangements, each coupling arrangement in said plurality of coupling arrangements being identical.

6. An arrangement as claimed in claim 5 wherein each of said local coil electronics comprises said surface for detuning the local coil, and wherein said local coil electronics are respectively individually operable to selectively detune any of said plurality of local coils that are not needed to implement said magnetic resonance examination.

7. An arrangement as claimed in claim 1 comprising a plurality of local coils respectively integrated into a plurality of fastening belts, each of said local coils having a width and the respective width of said local coils being identical.

8. An arrangement as claimed in claim 1 wherein said fastening belt with said local coil integrated therein forms a flexible, limp coil belt.

9. An arrangement as claimed in claim 1 comprising a belt connection connecting said fastening belt to said platform, said belt connection being selected from the group consisting of mechanical connectors and electrical connectors.

10. An arrangement as claimed in claim 9 wherein said belt connector comprises a plug connector, and wherein said plug connector is located at lateral side of said platform.

11. An arrangement as claimed in claim 1 wherein said fastening belt with said local coil integrated therein is configured to fix the patient on said platform.

12. An arrangement as claimed in claim 1 wherein said fastening belt is comprised of two connectible belt parts, said belt parts respectively overlapping each other to allow said fastening belt with said local coil integrated therein to be adapted to respective, differently-sized patients.

13. An arrangement as claimed in claim 12 comprising a hook-and-loop fastener that mechanically connects said belt parts to each other on the patient, said hook-and-loop fastener being configured with steps of a predetermined size that allows step-by-step loosening and tightening of the fastening belt on the patient, to control a degree of said overlapping.

14. An arrangement as claimed in claim 13 wherein said stepped structure comprises a mechanical catch.

15. An arrangement as claimed in claim 1 wherein said fastening belt is comprised of two belt parts, and comprising a hook-and-loop fastener that releasably connects said two belt parts to each other on said patient.

16. An arrangement as claimed in claim 1 wherein said local coil is configured as a magnetic resonance top coil.

17. An arrangement as claimed in claim 1 wherein said platform comprises a separable connection configured to allow said platform to be separated from said magnetic resonance apparatus.

18. An arrangement as claimed in claim 1 wherein said fastening belt is removably connected to said platform to allow replacement thereof by a rigid local coil in a predetermined body region of the patient.
